(19) United States
(12) Patent Application Publication
(10) Pub. No.: US 2011/0079351 A1
(43) Pub. Date: Apr. 7, 2011

(54) METHOD OF FILING ADHESIVE AND METHOD OF MANUFACTURING HEAD SUSPENSION

(75) Inventor: Eijiro FURUTA, Aikoh-gun (JP)

(73) Assignee: NHK SPRING CO., LTD., Yokohama-shi (JP)

(21) Appl. No.: 12/895,049

(22) Filed: Sep. 30, 2010

(30) Foreign Application Priority Data
Oct. 2, 2009 (JP) 2009-230903

(51) Int. Cl. H01L 41/22; B05D 3/06; B32B 37/12

(52) U.S. Cl. 156/275.5; 427/331; 427/595; 427/558

(57) ABSTRACT

A method of filling an adhesive into a gap includes steps of introducing one or more capsules containing the adhesive having an adhering function and a setting function into the gap, discharging the adhesive from the adhesive capsules by applying energy to the adhesive capsules in the gap, and setting the adhesive in the gap by applying energy to the discharged adhesive. The method can easily fill the adhesive 1 into the gap 7 without achieving a pressure-bonding process.

### BACKGROUND OF THE INVENTION

1. Field of the Invention

The present invention relates to a method of filling an adhesive into a gap and a method of manufacturing a head suspension employing the adhesive filling method to fix a piezoelectric element to the head suspension.

2. Description of Related Art

A technique of employing an adhesive capsule containing an adhesive to bond objects together is described in, for example, Japanese Unexamined Patent Application Publication No. S63-275688.

The adhesive capsule of this related art contains a viscous fluid (sealing material) that is thermally cured as an adhesive and solid particles serving as a spacer. The related art is capable of strongly bonding substrates together with a uniform gap kept between the substrates.

The related art places the adhesive capsule between substrates and applies pressure to the substrates so that the adhesive oozes out of the capsule and bonds the substrates together. This pressure-bonding process of the related art is inappropriate for cases that must avoid pressure to be applied to bonding objects such as substrates.

### SUMMARY OF THE INVENTION

An object of the present invention is to provide a method of filling an adhesive into a gap without employing the pressure-bonding process.

In order to accomplish the object, an aspect of the present invention provides a method of filling an adhesive into a gap, including steps of introducing one or more adhesive capsules containing the adhesive having an adhering function and a setting function into the gap, discharging the adhesive from the adhesive capsules by applying energy to the adhesive capsules in the gap, and setting the adhesive in the gap by applying energy to the discharged adhesive.

This aspect of the present invention is capable of easily filling an adhesive into a gap and setting the adhesive in the gap without conducting the pressure-bonding process.

### BRIEF DESCRIPTION OF THE DRAWINGS

FIG. 1 is an explanatory view illustrating a method of filling an adhesive into a gap according to a first embodiment of the present invention;

FIG. 2 is a perspective view illustrating a head suspension according to a second embodiment of the present invention;

FIG. 3A is a plan view illustrating a piezoelectric actuator on the head suspension of FIG. 2;

FIG. 3B is a sectional view taken along a line IIIB-IIIB of FIG. 3A; and FIG. 4 is an explanatory view illustrating bonding a piezoelectric element to an opening of the head suspension of FIG. 2.

### DETAILED DESCRIPTION OF EMBODIMENTS

A method according to the present invention fills an adhesive into a gap without employing the pressure-bonding process. To achieve this, the method includes steps of introducing one or more adhesive capsules containing the adhesive having an adhering function and a setting function into the gap, discharging the adhesive from the adhesive capsule by applying energy to the adhesive capsule in the gap, and setting the adhesive in the gap by applying energy to the discharged adhesive.

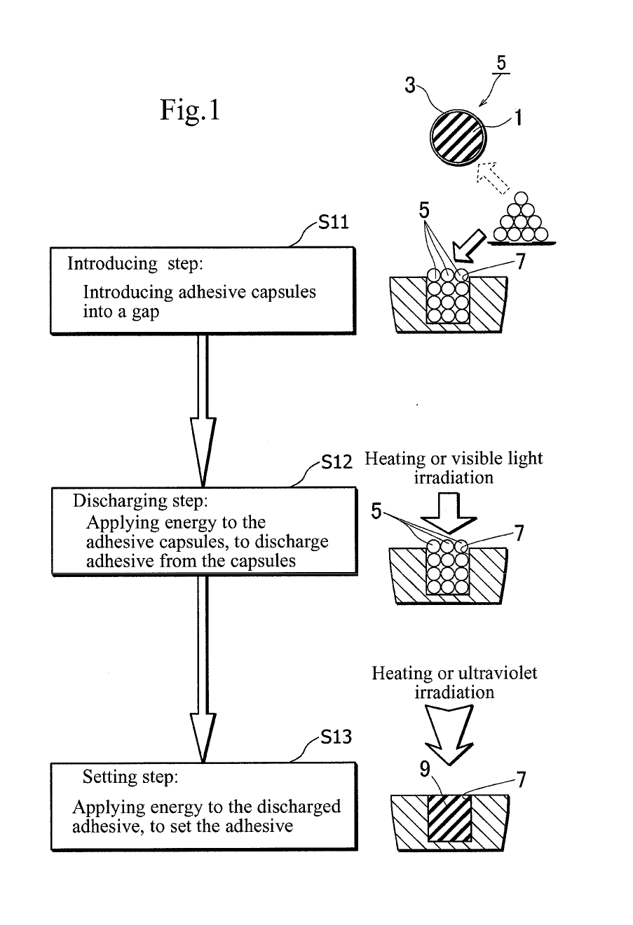

Now, a method of filling an adhesive into a gap according to the first embodiment of the present invention will be explained in detail with reference to FIG. 1.

In FIG. 1, the method includes an introducing step S11, a discharging step S12, and a setting step S13.

The introducing step S11 introduces adhesive capsules 5 into a gap 7, each adhesive capsule 5 being made of a shell or capsule 3 containing an adhesive 1.

The adhesive 1 basically has an adhering function and a setting function and is, for example, a thermosetting adhesive, an ultraviolet curing adhesive, or an aerobic curing adhesive. The adhesive 1 may be conductive or nonconductive.

The capsule 3 is, for example, a very fine microcapsule that is spherical having a diameter of about 1 to 1000 μm and is smaller than the dimensions of the gap 7. The capsule 3 is produced with the use of a chemical or physical technique. The capsule 3 protects the adhesive 1 from an atmosphere such as moisture and oxygen and improves the handling of the adhesive 1.

A manufacturing method of the adhesive capsules 5 is properly selected depending on the characteristics of the adhesive 1 from, for example, an interfacial polymerization method, an in-situ polymerization method, a submerged curing and coating method (an orifice method), a water-solution-based phase separation (coacervation) method, an organic-solution-based phase separation method, a submerged drying method, and a fusion dispersion cooling method.

The gap 7 is a space between objects. For example, the gap 7 is a recess formed on a single object, or a space between different objects that are assembled together.

Into the gap 7, the adhesive capsules 5 are introduced to completely fill the gap 7. If each adhesive capsule 5 is spherical, the adhesive capsules 5 filled in the gap 7 will involve voids among them.

To fill such voids with the adhesive 1 in following steps, a sufficient quantity of the adhesive capsules 5 must be introduced into the gap 7. The quantity of the adhesive capsules 5 to be introduced into the gap 7 is controllable according to the number of the adhesive capsules 5 if each adhesive capsule 5 contains the same quantity of the adhesive 1.

The discharging step S12 applies energy to the adhesive capsules 5 introduced into the gap 7, to discharge the adhesive 1 from the adhesive capsules 5. The adhesive 1 sealed in the adhesive capsules 5 comes out of the capsules 3, to demonstrate the original adhering and setting functions thereof.

The energy applied to the adhesive capsules 5 is properly determined according to various factors related to the adhesive capsules 5, such as the material of the capsule 3 and the setting characteristic of the adhesive 1 contained in the capsule 3. In this embodiment, the discharging step S12 applies one of thermal energy and light irradiation energy. If the adhesive 1 is of thermosetting, the capsule 3 is set to be thermally-fracturable, thermally-meltable, thermally-expandable or the like and thermal energy by heating will be applied, and if it is of ultraviolet curing, the capsule 3 is set to be thermally-fracturable, thermally-meltable, thermally-expandable or the like and thermal energy by visible light irradiation will be applied to discharge the adhesive 1 from the capsules 3.

In the case of the capsule 3 being thermally-fracturable or thermally-meltable, the capsule 3 is broken or melts with the thermal energy, to expose and discharge the adhesive 1 outward from the capsule 3, for example. In the case of the capsule 3 being thermally-expandable, the capsule 3 is expanded with the thermal energy and the adhesive 1 contained in the capsule 3 is reduced in viscosity so that the adhesive 1 oozes from the capsule 3, for example.

The setting step S13 applies energy to the discharged adhesive 1, to set or cure the adhesive 1. As a result, the adhesive 1 came out of the adhesive capsules 5 demonstrates the original adhering and setting functions, to form an adhesive layer 9 that completely fills the gap 7.

The energy applied to the discharged adhesive 1 may be thermal energy by heating if the adhesive 1 is a thermosetting adhesive and energy by ultraviolet irradiation if the adhesive 1 is an ultraviolet curing adhesive.

Although the first embodiment separately conducts the discharging step S12 and setting step S13, the steps S12 and S13 are sequentially achievable as a contiguous step.

If the adhesive 1 is a thermosetting adhesive, the discharging step S12 applies thermal energy to discharge the adhesive 1 from the adhesive capsules 5 and the setting step S13 continues the application of thermal energy to cure the adhesive 1 discharged from the adhesive capsules 5. In this way, the discharging step S12 and setting step S13 may continuously be carried out as a single step, to apply thermal energy to the adhesive capsules 5 and adhesive 1.

If the adhesive 1 is an ultraviolet curing adhesive, a lamp capable of alternatively emitting visible light or ultraviolet light is prepared. The discharging step S12 applies thermal energy by visible light irradiation to discharge the adhesive 1 from the adhesive capsules 5 and the setting step S13 switches the lamp to irradiate ultraviolet rays to cure the discharged adhesive 1. In this way, the visible light is switched to the ultraviolet light at proper timing, to continuously carry out the discharging step S12 and setting step S13 as a single step.

As mentioned above, the method according to the first embodiment conducts introducing the adhesive capsules 5 containing the adhesive 1 having an adhering function and a setting function into the gap 7 (the introducing step S11), discharging the adhesive 1 from the adhesive capsules 5 by applying energy to the adhesive capsules 5 in the gap 7 (the discharging step S12), and setting the adhesive 1 in the gap 7 by applying energy to the discharged adhesive 1 (the setting step S13). The first embodiment, therefore, can easily fill the adhesive 1 into the gap 7 without achieving the pressure-bonding process.

A method of manufacturing a head suspension according to the second embodiment of the present invention will be explained. This method uses the adhesive filling method of the first embodiment.

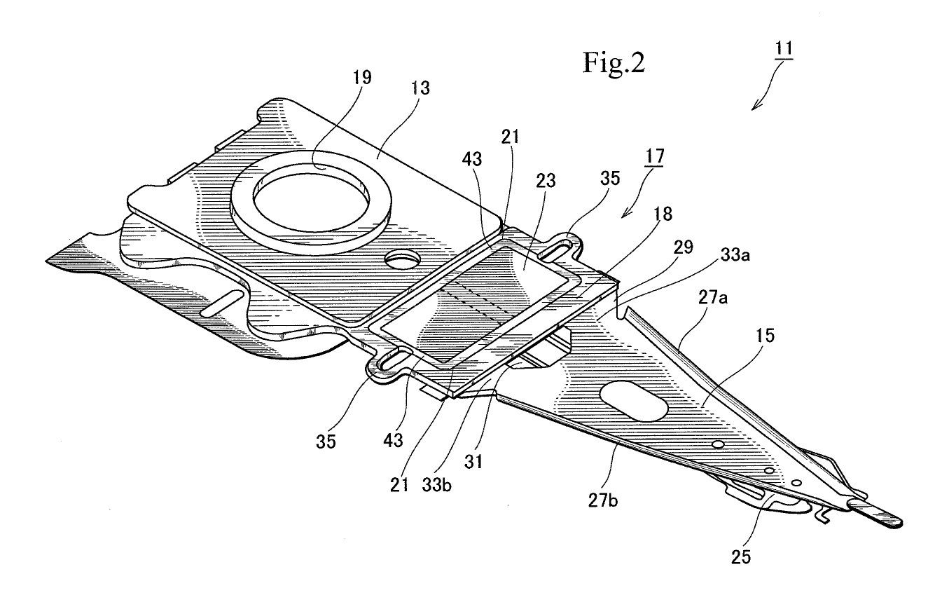

FIG. 2 is a perspective view illustrating the head suspension 11 according to the second embodiment. The head suspension 11 is used to write and read information to and from a magnetic disk drive (not illustrated) and has a base plate 13, a load beam 15, and an actuator base 18.

The base plate 13 resiliently supports the load beam 15 through the actuator base 18. The base plate 13 is made of a thin metal plate such as a stainless steel plate having a thickness of, for example, about 150 to 200 μm.

The base plate 13 has a circular boss 19. With the boss 19, the base plate 13 is attached to a front end of an actuator arm (not illustrated) driven by a voice coil motor (not illustrated).

The load beam 15 applies load onto a magnetic head slider (not illustrated) arranged at a front end of the load beam 15. The load beam 15 is made of a resilient thin metal plate such as a stainless steel plate having a thickness of, for example, about 50 to 150 μm.

The actuator base 18 is interposed between the base plate 13 and the load beam 15 and supports a piezoelectric element 23 that deforms in response to an applied voltage. The actuator base 18 may be integral with or separate from the base plate 13.

When the base plate 13 and actuator base 18 are integral with each other, the base plate 13 serves as a base having an opening to be explained later in which the piezoelectric element 23 is arranged. When the base plate 13 and actuator base 18 are discrete parts, the actuator base 18 serves as the base.

The load beam 15 is provided with a flexure 25 whose front end supports the magnetic head slider (not illustrated).

Each side of the load beam 15 has a bent edge 27a (27b). The bent edges 27a and 27b function to improve the rigidity of the load beam 15.

A rear end of the load beam 15 is integral with a connection plate 29. The connection plate 29 is made of a resilient thin metal plate such as a stainless steel plate having a thickness of, for example, about 30 μm. The connection plate 29 has a hole 31 to reduce the thickness-direction bending rigidity and weight of the head suspension 11. On the sides of the hole 31, hinges 33a and 33b are formed to be bendable in a thickness direction.

On a rear end of the connection plate 29, i.e., a base of the load beam 15, a front end of the actuator base 18 is laid and is fixed by, for example, laser welding.

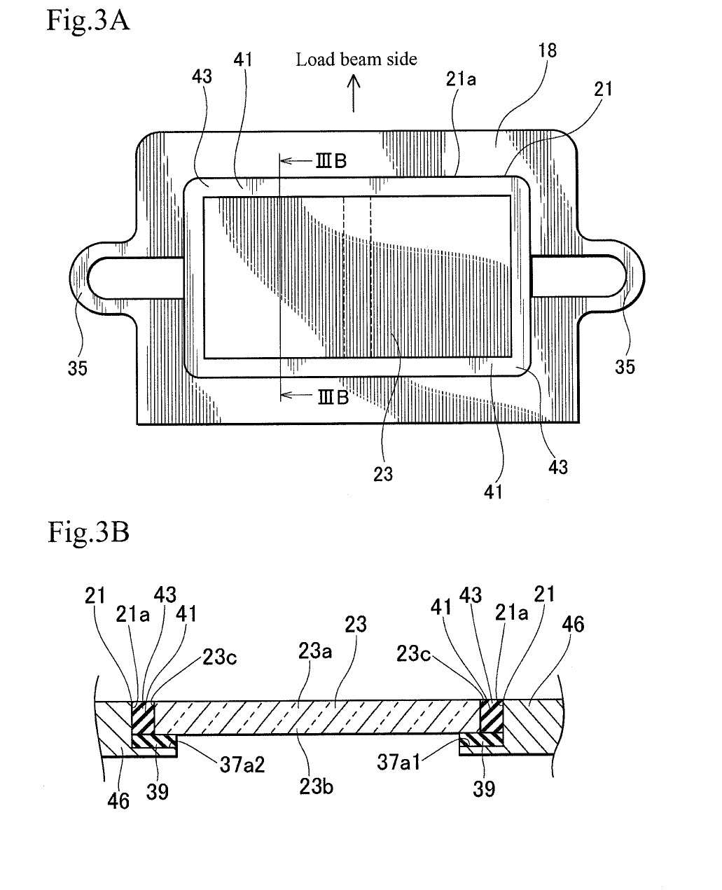

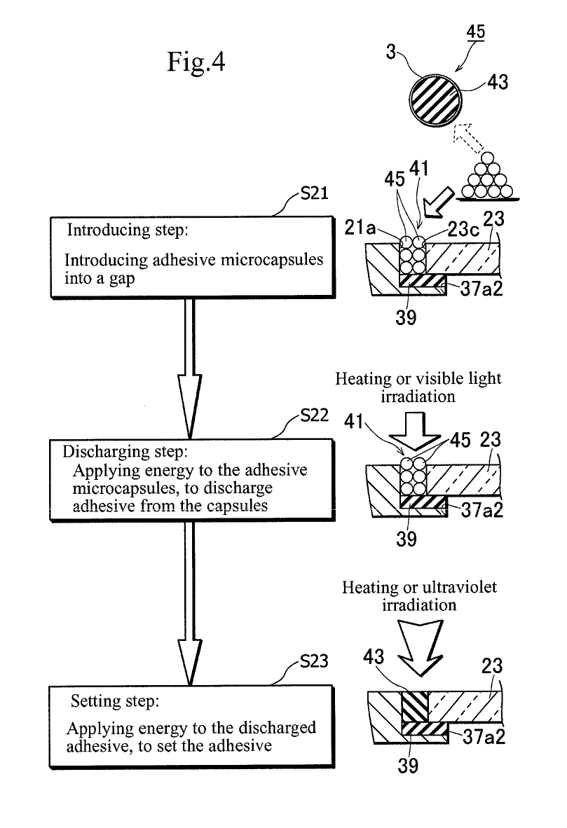

A piezoelectric actuator 17 installed on the head suspension 11 of the second embodiment will be explained. FIG. 3A is a plan view illustrating the piezoelectric actuator 17 installed on the head suspension 11 of FIG. 2 and FIG. 3B is a sectional view taken along a line IIIB-IIIB of FIG. 3A.

When designing the piezoelectric actuator 17, considerations must be made to effectively transfer a strain (displacement) of the piezoelectric element 23, which occurs depending on a voltage applied to the element 23, to the load beam 15, to secure electrical insulation between an electrode of the piezoelectric element 23 and the actuator base 18, to prevent dust from dropping off side surfaces of the piezoelectric element 23, and to protect the piezoelectric element 23 that is brittle from being damaged.

In consideration of these factors, the piezoelectric element 23 of the piezoelectric actuator 17 according to the second embodiment is embedded in an opening 21 formed through the actuator base 18, as illustrated in FIGS. 2 to 3B.

The opening 21 is rectangular to receive the piezoelectric element 23. When the piezoelectric element 23 is embedded in the opening 21 of the actuator base 18, a top face of the base plate 13 is flush with the surface of an upper electrode 23a of the piezoelectric element 23.

On each side of the opening 21, a flexible link 35 having a U-shape is formed to the actuator base 18. The flexible links 35 improve the rigidity of the piezoelectric actuator 17 without bothering a displacement (deformation) stroke of the piezoelectric actuator 17 in a sway direction.

Front and rear sides of the opening 21 have receivers 37a1 and 37a2 to widthwise support a lower electrode 23b of the piezoelectric element 23. The receivers 37a1 and 37a2 are integral with the actuator base 18 in the opening 21 and are formed by half-etching. Namely, the actuator base 18 formed from a thin metal plate is chemically etched so that parts of the actuator base 18 corresponding to the receivers 37a1 and 37a2 are thinned from the remaining part of the actuator base 18.

Between the lower electrode 23b of the piezoelectric element 13 and the receivers 37a1 and 37a2, there is formed a nonconductive adhesive layer 39 having a proper thickness, as illustrated in FIG. 3B.

The piezoelectric element 23 embedded in the opening 21 is rectangular and has outer dimensions that are slightly smaller than inner dimensions of the opening 21 that is also rectangular.

When the piezoelectric element 23 is placed at a predetermined position in the opening 21, there is formed a rectangular circumferential channel between an inner side face 21 a of the opening 21 and an outer side face 23c of the piezoelectric element 23. This rectangular circumferential channel is a gap 41.

The gap 41 is completely filled with a nonconductive adhesive 43 so that a strain (displacement) of the piezoelectric element 23 is correctly transferred to the load beam 15. With the nonconductive adhesive 43 entirely filled in the gap 41, the piezoelectric element 23 is surely fixed to the opening 21.

A process of fixing the piezoelectric element 23 to the opening 21 of the head suspension 11 according to the second embodiment will be explained with reference to FIG. 4 also. FIG. 4 is an explanatory view illustrating bonding a piezoelectric element to an opening of the head suspension of FIG. 2.

Step S21 is an introducing step. Into the gap 41 between the inner side face 21a of the opening 21 and the outer side face 23c of the piezoelectric element 23, adhesive microcapsules 45 are filled as illustrated in FIG. 4. Each of the adhesive microcapsules 45 is a spherical microcapsule 3 containing a nonconductive adhesive 43 that is thermosetting or ultraviolet curing.

Step S22 is a discharging step. Thermal energy or light irradiation energy is applied to the adhesive microcapsules 45 introduced in the gap 41, to break the capsule 45 and discharge the nonconductive adhesive 43 from each capsule 45. The discharged nonconductive adhesive 43 starts to demonstrate original adhering and setting functions.

Step S23 is a setting step. Thermal energy or ultraviolet irradiation energy is applied to the discharged nonconductive adhesive 43, to set or cure the adhesive 43. The adhesive 43 demonstrates the original adhering, curing, and insulating functions.

The adhesive 43 in the gap 41 forms a nonconductive adhesive layer 43 that wholly fills the gap 41 and surely fixes the piezoelectric element 23 to the opening 21 as illustrated in FIGS. 3B and 4.

Although the second embodiment separately carries out the discharging step S22 and setting step S23, the steps S22 and S23 may continuously be carried out as a single step.

If the nonconductive adhesive 43 is a thermosetting adhesive, the discharging step S22 applies thermal energy to discharge the adhesive 43 from the capsules 45 and the setting step S23 continues the application of thermal energy to cure the adhesive 43 discharged from the capsules 45. In this way, the discharging step S22 and setting step S23 may continuously be carried out as a single step, to apply thermal energy to the capsules 45 and nonconductive adhesive 43.

If the nonconductive adhesive 43 is an ultraviolet curing adhesive, a lamp capable of alternatively emitting visible light and ultraviolet light is prepared. The discharging step S22 applies thermal energy by visible light irradiation to discharge the adhesive 43 from the capsules 45 and the setting step S23 switches the lamp to irradiate ultraviolet rays to cure the discharged adhesive 43. In this way, the visible light is switched to the ultraviolet light at proper timing, to continuously carry out the discharging step S22 and setting step S23 as a single step.

As mentioned above, the method according to the second embodiment conducts introducing the adhesive microcapsules 45 each containing the nonconductive adhesive 43 having one of thermosetting characteristic and ultraviolet curing characteristic into the gap 41 between the inner side face 21a of the opening 21 and the outer side face 23c of the piezoelectric element 23, thereby filling the gap 41 with the adhesive microcapsules 45 (the introducing step S21), discharging the nonconductive adhesive 43 from the adhesive microcapsules 45 by applying one of thermal energy and light irradiation energy to the adhesive microcapsules 45 in the gap 41 (the discharging step S22), and setting the nonconductive adhesive 43 in the gap 41 by applying one of thermal energy and ultraviolet irradiation energy to the discharged nonconductive adhesive 43, thereby fixing the piezoelectric element 23 to the opening 21 with the nonconductive adhesive 43 (the setting step S23). The second embodiment, therefore, can easily fill the nonconductive adhesive 43 into the gap 41 without achieving the pressure-bonding process.

According to the second embodiment, the adhesive microcapsule 45 may have the same rectangular shape as the rectangular gap 41. In this case, introducing the one adhesive microcapsule 45 into the gap 41 is simply carried out by fitting the microcapsule 45 into the gap 41. This simplifies the introducing step S21.

According to the second embodiment, the discharging step S22 may directly apply thermal energy or light irradiation energy from the opening 21 to the adhesive microcapsules 45, to discharge the nonconductive adhesive 43 from the microcapsules 45. This quickly discharges the adhesive 43 out of the microcapsules 45 and improves the efficiency of the discharging step S22.

According to the second embodiment, the setting step S23 may directly apply thermal energy or ultraviolet irradiation energy from the opening 21 to the discharged nonconductive adhesive 43, to set or cure the adhesive 43. This quickly cures the adhesive 43 and improves the efficiency of the setting step S23.

Operation of the head suspension 11 manufactured according to the second embodiment will be explained.

When receiving a signal of electric power, the piezoelectric element 23 fixed to the opening 21 deforms into a trapezoidal shape with one side of the piezoelectric element 23 elongating in a direction along a center axis (corresponding to two dotted lines in FIG. 2) and the other side thereof contracting in a direction along the center axis.

Depending on the deformation and displacement stroke of the piezoelectric element 23, the piezoelectric actuator 17 moves a front end of the load beam 15 in a sway direction (a widthwise direction of the load beam 15) for a very small distance.

According to the second embodiment, the nonconductive adhesive 43 entirely fills the gap 41 between the inner side face 21 a of the opening 21 of the head suspension 11 and the outer side face 23c of the piezoelectric element 23, to fix the piezoelectric element 23 to the opening 21. This configuration correctly transfers a distortion (displacement) of the piezoelectric element 23 to the load beam 15.

According to the second embodiment, the nonconductive adhesive layers 39 and 43 interposed between the piezoelectric element 23 and the actuator base 18 secure electric insulation between them.

According to the second embodiment, the outer side face 23c of the piezoelectric element 23 is entirely covered with the nonconductive adhesive layer 43, to surely prevent dust from dropping off the outer side face 23c of the piezoelectric element 23.

According to the second embodiment, the piezoelectric element 23 is fixed to the opening 21 with the nonconductive adhesive layers 39 and 43, and therefore, the piezoelectric element 23 that is brittle is surely protected from being damaged.

The present invention is not limited to the embodiments mentioned above. Various modifications will be possible based on the teachings and technical ideas suggested in the specification and claims. Methods of filling adhesive and methods of manufacturing head suspensions according to such modifications also fall in the scope of the present invention.

Although the adhesive filling method according to the embodiment includes the introducing step, discharging step, and setting step, this does not limit the present invention. For example, the present invention may employ a lump of adhesive whose adhering and setting functions are sealed at ordinary temperature and pressure and which is easy to handle. Such an adhesive is not required to be packed in capsules.

The adhesive lump that demonstrates no adhering function or setting function at ordinary temperature and pressure is easy to handle because the functions of the adhesive lump is released only when it receives thermal energy, pressure, or ultraviolet irradiation energy. An example of such an adhesive is a reactive structural hot melt adhesive. Unlike a general hot melt adhesive such as a thermoplastic resin adhesive, the reactive structural hot melt adhesive melts by heat, reacts with environmental water, and sets to form a bridged structure, and therefore, is usable as a structural adhesive. When receiving thermal energy, pressure, or ultraviolet irradiation energy, the structural adhesive demonstrates adhering and setting functions, and therefore, can omit the discharging step (S12, S22) to discharge the adhesive from capsules.

Namely, a modification of the present invention may cover a method of filling one or more lumps of adhesive into a gap, the lumps each having an adhering function and a setting function that are sealed at ordinary temperature and pressure, and therefore, being easy to handle at the ordinary temperature and pressure. The method includes introducing the lumps into the gap and applying energy to lumps in the gap, thereby releasing the adhering function and setting function of the adhesive and setting the adhesive in the gap.

To easily handle an adhesive, the first embodiment seals the adhesive into a capsule. Unlike this, the above-mentioned modification employs the characteristic of the adhesive that the adhesive demonstrates no adhering or setting function at ordinary temperature and pressure, and therefore, can eliminate the discharging step. The introducing and setting steps of the modification are the same as those of the first embodiment, and therefore, will not be explained.

What is claimed is:

1. A method of filling an adhesive into a gap, comprising steps of:
introducing one or more capsules containing the adhesive having an adhering function and a setting function into the gap;
discharging the adhesive from the adhesive capsules by applying energy to the adhesive capsules in the gap; and
setting the adhesive in the gap by applying energy to the discharged adhesive.

2. The method of claim 1, wherein the discharging step applies one of thermal energy and light irradiation energy to the adhesive capsules, thereby discharging the adhesive from the adhesive capsules.

3. The method of claim 1, wherein the adhesive is one of a thermosetting adhesive and an ultraviolet curing adhesive, and
the setting step applies one of thermal energy and ultraviolet irradiation energy to the discharged adhesive, thereby setting the adhesive in the gap.

4. The method of claim 1, wherein the adhesive capsules is spherical and has a diameter smaller than the dimensions of the gap.

5. The method of claim 1, wherein the introducing step introduces a plurality of the adhesive capsules into the gap so that the gap is filled with the adhesive capsules.

6. A method of filling an adhesive into a gap, comprising:
introducing one or more lumps of the adhesive into the gap, the lumps each having an adhering function and a setting function that are sealed at ordinary temperature and pressure, and therefore, being easy to handle at the ordinary temperature and pressure; and
releasing the adhering function and setting function of the adhesive and setting the adhesive in the gap by applying energy to the lumps in the gap.

7. A method of manufacturing a head suspension, the head suspension having a piezoelectric element, a base having an opening in which the piezoelectric element is arranged, and a load beam attached to the base, the piezoelectric element deforming in response to electric power applied thereto, to move a front end of the load beam in a sway direction, the method comprising steps of:
introducing one or more microcapsules each containing a nonconductive adhesive having one of a thermosetting characteristic and an ultraviolet curing characteristic into a gap between an inner side face of the opening and an outer side face of the piezoelectric element, thereby filling the gap with the microcapsules;
discharging the nonconductive adhesive from the microcapsules by applying one of thermal energy and light irradiation energy to the microcapsules in the gap; and
setting the nonconductive adhesive in the gap by applying one of thermal energy and ultraviolet irradiation energy to the discharged nonconductive adhesive, thereby fixing the piezoelectric element to the opening with the nonconductive adhesive.

8. The method of claim 7, wherein the introducing step introduces the one microcapsule into the gap and the one microcapsule is shaped to fill the gap.

9. The method of claim 7, wherein the discharging step directly applies the one of thermal energy and light irradiation energy from the opening to the microcapsules in the gap, thereby discharging the nonconductive adhesive from the microcapsules.

10. The method of claim 7, wherein the setting step directly applies the one of thermal energy and ultraviolet irradiation energy from the opening to the microcapsules, thereby setting the nonconductive adhesive in the gap and fixing the piezoelectric element to the opening with the nonconductive adhesive.
